(19) United States
(12) Patent Application Publication
(10) Pub. No.: US 2020/0047181 A1
(43) Pub. Date: Feb. 13, 2020

(54) Sample Processing Device

(71) Applicant: Hitachi High-Technologies Corporation, Minato-ku, Tokyo (JP)

(72) Inventors: Yoshihiro NAGAOKA, Tokyo (JP); Motohiro YAMAZAKI, Tokyo (JP)

(21) Appl. No.: 16/609,248

(22) PCT Filed: May 11, 2018
(86) PCT No.: PCT/JP2018/018259

§ 371 Date: Oct. 29, 2019

(30) Foreign Application Priority Data
Jun. 26, 2017 (JP) 2017-123833

(51) Int. Cl. B01L 3/00; G01N 35/02; G01N 35/08; B81B 3/00

(52) U.S. Cl. CPC B01L 3/502715; G01N 35/02; G01N 2035/0479; B81B 3/00; B01L 3/502738; G01N 35/08

(57) ABSTRACT

This sample processing device comprises: an analysis chip having a flow path on a lower surface side; a drive unit having a plurality of recesses on an upper surface side; an elastic film positioned between the analysis chip and the drive unit; and an air pressure control unit that switches whether the elastic film is adhered to the analysis chip side or adhered to the drive unit side. The analysis chip includes a quantitative flow path for quantifying liquid, and at least four branch flow paths branched from the quantitative flow path. The drive unit includes recesses below each of the ends of the four branch flow paths not on the quantitative flow path side, and each of the recesses communicates with the air pressure control unit.

### TECHNICAL FIELD

The present invention relates to a sample processing device.

### BACKGROUND ART

PTL 1 describes a microfluidic system and method. This patent literature describes “a microfluidic system includes a rigid layer, an elastic layer, a fluid chamber or channel between the rigid layer and the elastic layer, and control means for deforming the elastic layer for manipulating a fluid in the fluid chamber or channel.”

### CITATION LIST

### Patent Literature

PTL 1: WO2010/073020

### SUMMARY OF INVENTION

### Technical Problem

PTL 1 describes the microfluidic system comprising the control means for deforming the elastic layer for manipulating the fluid in the fluid chamber or channel. However, the microfluidic system described in PTL 1 achieves a predetermined volumetric flow rate, i.e., a predetermined volume of a fluid flowing per unit time through a repetition of deformation of the elastic layer, but is not described with regard to manipulation of metering a predetermined amount of fluid. Therefore, there has been a problem that manipulation of processing to withdraw part of fluid in a predetermined amount, e.g., manipulation of mixing two types of fluid at a certain volume ratio could not achieve a volume ratio with sufficient precision.

It is an object of the present invention to provide a sample processing device that can meter a fluid through deformation of an elastic membrane.

### Solution to Problem

In order to solve the aforementioned problem, a representative sample processing device of the present invention is achieved by a sample processing device including: an analysis chip including a flow path on a lower surface side; a drive portion including a plurality of recesses on an upper surface side; an elastic membrane positioned between the analysis chip and the drive portion; and an air pressure control portion configured to switch whether the elastic membrane is closely attached to an analysis chip side or closely attached to a drive portion side, wherein the analysis chip includes a metering flow path for metering a liquid and at least four branch flow paths branched from the metering flow path, the drive portion includes a recess below each of an end of the four branch flow paths not on a metering flow path side, and each recess is in communication with the air pressure control portion.

### Advantageous Effects of Invention

According to the present invention, a sample processing device that can meter a fluid through deformation of an elastic membrane can be provided.

The problems, configurations, and effects other than those described above will be more clarified in a description of embodiments described below.

### BRIEF DESCRIPTION OF DRAWINGS

FIG. 1 is a top view and a cross-sectional side view of an analysis chip according to Example 1.

FIG. 2 is a top view and a side view of a sample processing device according to Example 1.

FIG. 3 is a diagram of an air pipe system for controlling pressure of a drive portion of the sample processing device according to Example 1.

FIG. 4 is a flowchart illustrating a manipulation flow of the sample processing device according to Example 1.

FIG. 5 is a flowchart illustrating an analysis operation flow of the sample processing device according to Example 1.

FIG. 6 is a flowchart illustrating a sample introduction operation flow of the sample processing device according to Example 1.

FIG. 7a is an explanatory view of a sample introduction operation of the sample processing device according to Example 1.

FIG. 7b is an explanatory view of a sample introduction operation of the sample processing device according to Example 1.

FIG. 8 is an explanatory view illustrating a sample holding state of the sample processing device according to Example 1.

FIG. 9 is a flowchart illustrating a sample disposal operation flow of the sample processing device according to Example 1.

FIG. 10a is an explanatory view of a sample disposal operation of the sample processing device according to Example 1.

FIG. 10b is an explanatory view of a sample disposal operation of the sample processing device according to Example 1.

FIG. 11 is a flowchart illustrating a sample cutout operation flow of the sample processing device according to Example 1.

FIG. 12a is an explanatory view of a sample cutout operation of the sample processing device according to Example 1.

FIG. 12b is an explanatory view of a sample cutout operation of the sample processing device according to Example 1.

FIG. 13 is a flowchart illustrating a reagent introduction operation flow of the sample processing device according to Example 1.

FIG. 14 is a flowchart illustrating a stirring operation flow of the sample processing device according to Example 1.

FIG. 15a is an explanatory view of stirring operation of the sample processing device according to Example 1.

FIG. 15b is an explanatory view of stirring operation of the sample processing device according to Example 1.

FIG. 16 is a flowchart illustrating a measurement operation flow of the sample processing device according to Example 1.

FIG. 17 is a top view and a cross-sectional side view of an analysis chip according to Example 2.

FIG. 18 is a top view and a cross-sectional side view of an analysis chip according to Example 3.

### DESCRIPTION OF EMBODIMENTS

Examples are described below in conjunction with the drawings.

### Example 1

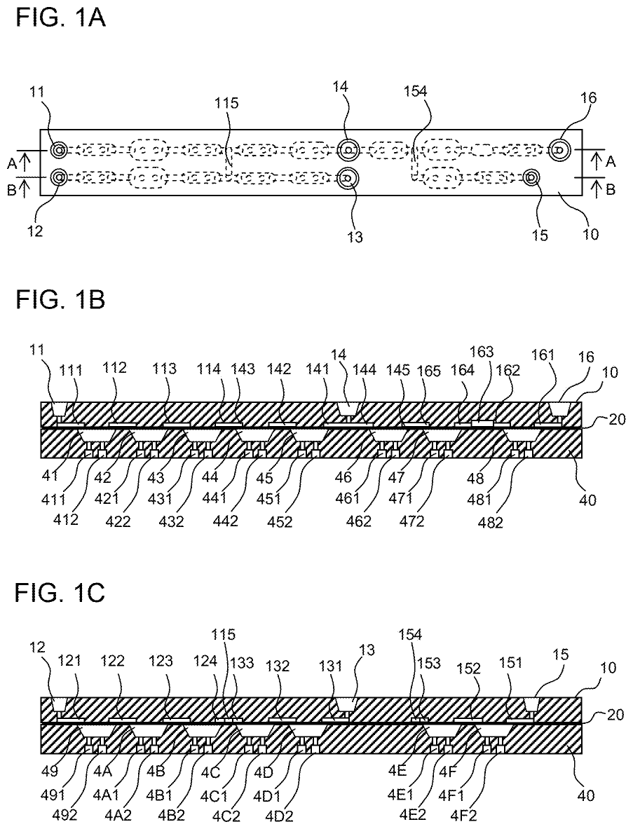

The sample processing device according to Example 1 is described below in conjunction with FIGS. 1 to 3. In the present example, a description is given of the sample processing device for performing optical measurement, e.g., identification and metering of a chemical substance, such that a sample of fluidized blood, urine, swab, or the like and a reagent are fluidized and mixed at a certain volume ratio in the sample processing device.

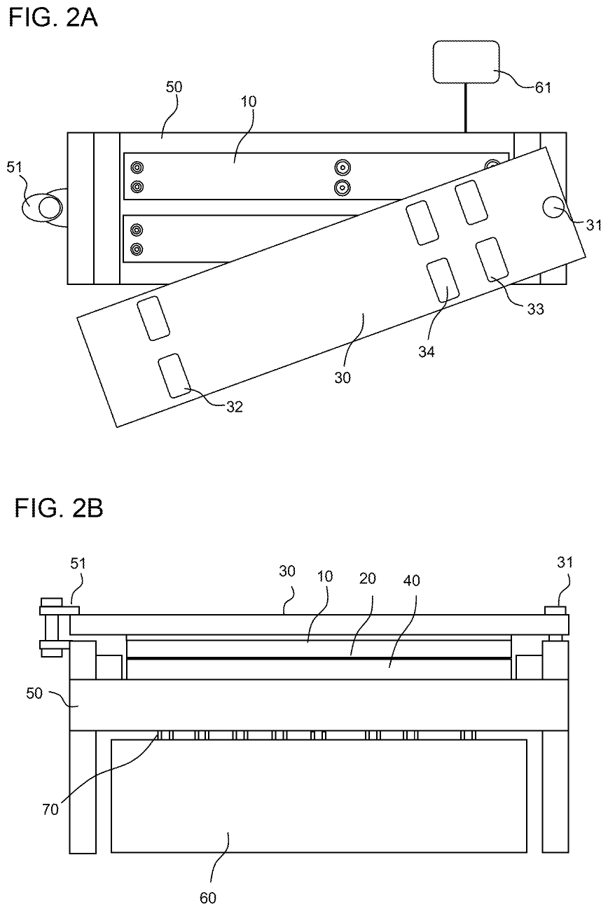

(A) and (B) of FIG. 2 illustrate a top view and a side view of the sample processing device according to Example 1, respectively. In the sample processing device of the drawing, an analysis chip 10 and a membrane 20 are pressed against a drive portion 40 by a lid 30. The lid 30 is rotatably supported about a rotary support portion 31, and (A) of FIG. 2 illustrates a state in which the lid 30 is partially opened, and two analysis chips 10 are arranged side by side. In (B) of FIG. 2, the lid 30 is fully closed and is fastened to a housing 50 by a locking mechanism 51. The lid 30 includes a sample input window 32 and a reagent input window 33 for respectively inputting a sample and a reagent to the analysis chip 10, and an observation window 34 for observing a result of analysis.

A control portion 60 for controlling air pressure in the drive portion 40 is provided below the housing 50, and an air pipe 70 is linked from the drive portion 40 to the control portion 60. The operation of the control portion 60 is controlled with a signal from a manipulation portion 61, which is outside of the device.

(A), (B), and (C) of FIG. 1 are respectively a top view, a cross-sectional side view (AA cross-section), and a cross-sectional side view (BB cross-section) in a state where the analysis chip according to Example 1 is closely attached to the drive portion via a membrane. FIG. 1 illustrates a state where the analysis chip 10 is attached to the sample processing device of FIG. 2 and the drive portion 40 is pressed by the lid 30 via a membrane 20. (A) of FIG. 1 is a view of the analysis chip 10 when viewed from an upper surface side in which a well, which is a container on the upper surface side of the analysis chip, is indicated by the solid line and a groove on the lower surface side of the analysis chip and a recess of the drive portion 40 are indicated by the dashed lines. (B) of FIG. 1 is AA cross-section of FIG. 1(A), and (C) of FIG. 1 is BB cross-section of FIG. 1(A), and the analysis chip 10 and the drive portion 40 are in contact with each other via the membrane 20.

The analysis chip 10 includes, on the upper surface side, a sample well 11, an air intake well 12, a sample disposal well 13, a stirring well 14, a reagent well 15, a mixture disposal well 16, which are containers, and, on the lower surface side, a plurality of grooves 111, 112, 113, 114, 115, 121, 122, 123, 124, 131, 132,133, 141, 142, 143, 144, 145, 151, 152, 153, 154, 161, 162, 163, 164, and 165.

The membrane 20 is an elastic body formed of a high polymer compound, e.g., rubber or resin, and is deformed by air pressure to move a fluid and is closely attached to the surfaces of the analysis chip 10 and the drive portion 40 to seal the fluid.

The drive portion 40 includes recesses 41, 42, 43, 44, 45, 46, 47, 48, 49, 4A, 4B, 4C, 4D, 4E, and 4F on the upper surface side that is closely attached to the membrane 20, and, from each recess, two types of pipe, i.e., a pressurization pipe 411, 421, 431, 441, 451, 461, 471, 481, 491, 4A1, 4B1, 4C1, 4D1, 4E1, and 4F1, and a depressurization pipe 412, 422, 432, 442, 452, 462, 472, 482, 492, 4A2, 4B2, 4C2, 4D2, 4E2, and 4F2 are connected to the air pipe 70 illustrated in FIG. 2.

FIG. 3 is a diagram of an air pipe system that is for control of pressure of the drive portion 40 of the present example and is set in the control portion 60. A pressurization pump 71 is branched to 15 systems each of which is further branched into two systems via a pressurization electromagnetic valve 711, 721, 731, 741, 751, 761, 771, 781, 791, 7A1, 7B1, 7C1, 7D1, 7E1, 7F1, and is connected to the pressurization pipe of the drive portion 40. The system is branched to two systems from the pressurization electromagnetic valve. This is because the sample processing device of the present example includes two analysis chips as illustrated in (A) of FIG. 2. Similarly, a depressurization pump 72 is branched into 15 systems each of which is further branched into two systems via a depressurization electromagnetic valve 712, 722, 732, 742, 752, 762, 772, 782, 792, 7A2, 7B2, 7C2, 7D2, 7E2, 7F2, and is connected to the depressurization pipe of the drive portion 40.

When the pressurization electromagnetic valve 711 or the like is energized, the air pipe is brought into communication from the pump 71 to the drive portion 40, and the groove 41 or the like of the drive portion 40 is pressurized. Meanwhile, in the case of not being energized, the air pipe on the pump 71 side is closed such that outflow from the air pipe on the drive portion 40 side to the outside, i.e., to the atmosphere side, is possible and inflow from the outside to the air pipe is not possible.

When the depressurization electromagnetic valve 712 or the like is energized, the air pipe is brought into communication from the pump 72 to the drive portion 40, and the groove 41 or the like of the drive portion 40 is depressurized. Meanwhile, in the case of not being energized, the air pipe on the pump 72 side is closed such that inflow from the atmosphere side to the air pipe on the drive portion 40 side is possible and outflow from the air pipe to the outside is not possible.

Manipulation of the sample processing device of the present example is described below in conjunction with the manipulation flow of FIG. 4. In a state before start of the manipulation, the drive portion 40 is set in the sample processing device and the air pipe 70 is connected. In analysis chip attachment 201, which is a first manipulation, a manipulator attaches the analysis chips 10 and the membrane 20 to the drive portion 40 and closes the lid 30. This state is (B) of FIG. 2. Note that typically the analysis chips 10 and the membrane 20 are collectively packaged, and the resulting package is attached to the drive portion 40.

Next, in device operation start 202, the manipulator selects a control procedure corresponding to the content of analysis on the manipulation portion 61 and starts device operation. The sample processing device starts initialization operation 203 and performs opening/closing operation of the electromagnetic valve, pressurization and depressurization manipulation with the pump, checking of pressure as necessary, or the like.

Then, in a state where the pressurization pump 71 and the depressurization pump 72 are operated, the depressurization electromagnetic valve 712 and the like are all closed, and in a state where at least the pressurization electromagnetic valves 711 and 7F1 are opened, standby state start 204 is provided.

In the standby state, in input manipulation 205, the manipulator inputs a sample into the sample well 11 through the sample input window 32 and similarly inputs a reagent into the reagent well 15 through the reagent input window 33. At this time, because the pressurization electromagnetic valves 711 and 7F1 are opened, the recesses 41 and 4F are pressurized and, at both groove portions, the membrane 20 is pressed against the lower surface of the analysis chip, such that the grooves 111 and 151 are sealed and the sample and the reagent do not flow out from the sample well 11 and the reagent well 15, respectively.

When input of the sample and the reagent is completed, the manipulator gives an instruction of analysis operation start 206 on the manipulation portion 61, and the sample processing device performs analysis operation 207. When the analysis ends, results of the analysis are stored in a memory of the sample processing device and are displayed on a display or the like of the manipulation portion 61 as necessary.

When the analysis operation 207 ends, in analysis chip removal 208, the manipulator removes the analysis chips 10 and the membrane 20 and stores or disposes of the analysis chips 10 and the membrane 20. When there is a subsequent analysis, returning to the analysis chip attachment 201, a new analysis chip is mounted and analysis is performed. When there is no analysis, the manipulator performs end manipulation 209 on the manipulation portion 61 and stops the device.

Next, the analysis operation 207 of the sample processing device of the present example is described in detail in conjunction with FIG. 5.

In sample introduction 212 of FIG. 5, the sample held in the sample well 11 is delivered to the sample disposal well 13 and is introduced into the metering groove 115. In sample disposal 213, air is introduced from the air intake well 12, and an excessive sample is disposed of in the sample disposal well 13. In sample cutout 214, air is introduced from the air intake well 12, and the sample held in the metering groove 115 is cut out to the stirring well 14. The aforementioned series of operations of the sample introduction 212, the sample disposal 213, and the sample cutout 214 is the sample metering 211 for metering the sample.

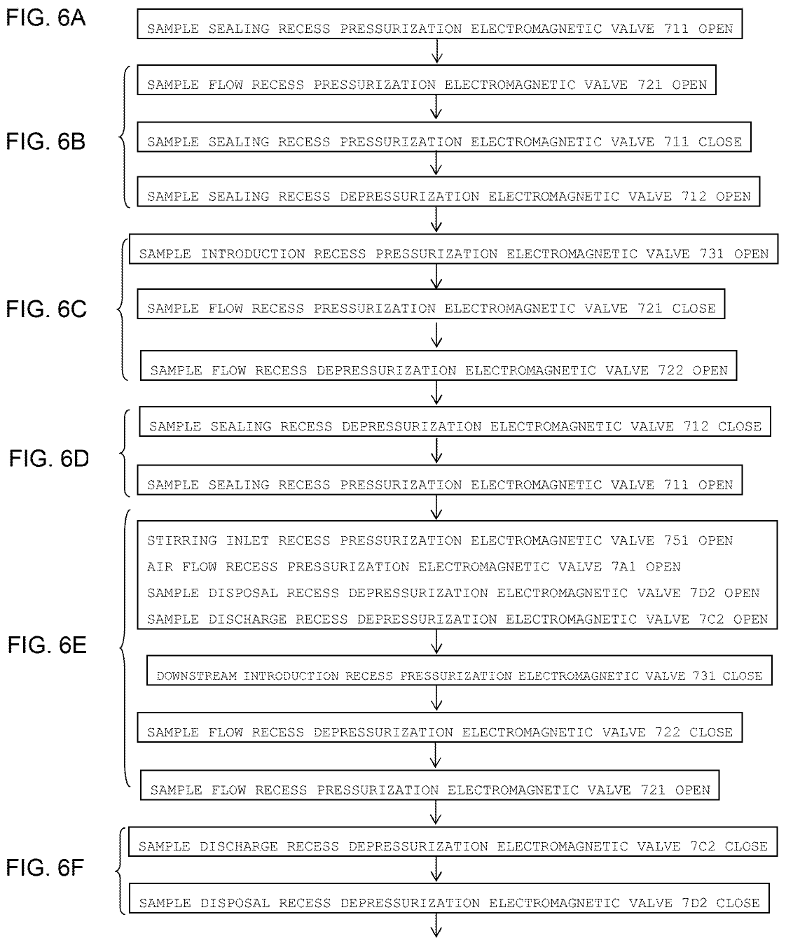

The sample metering 211 is described in detail below. First, the sample introduction 212 is described in conjunction with FIGS. 6, 7a, 7b, and 8.

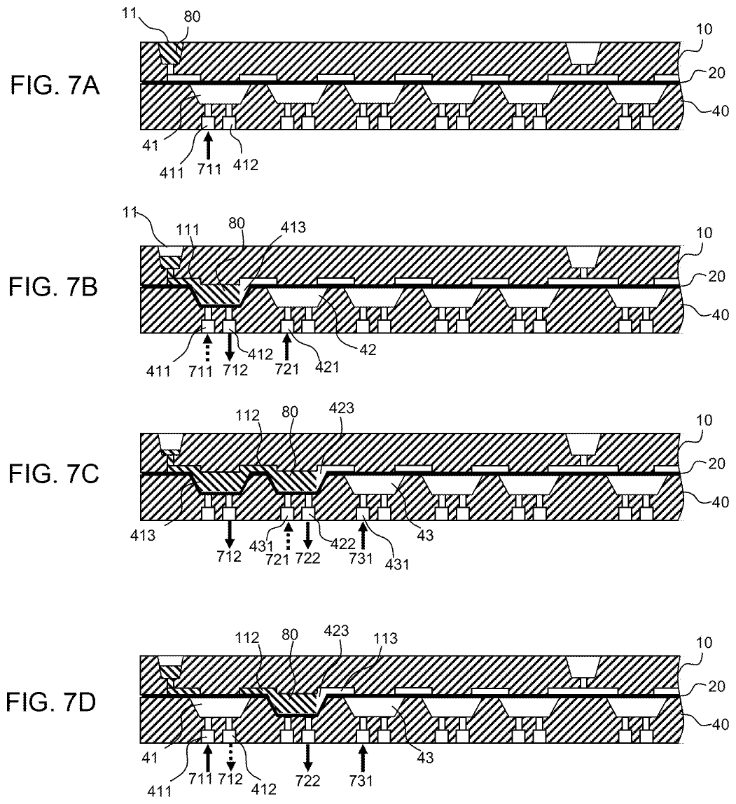

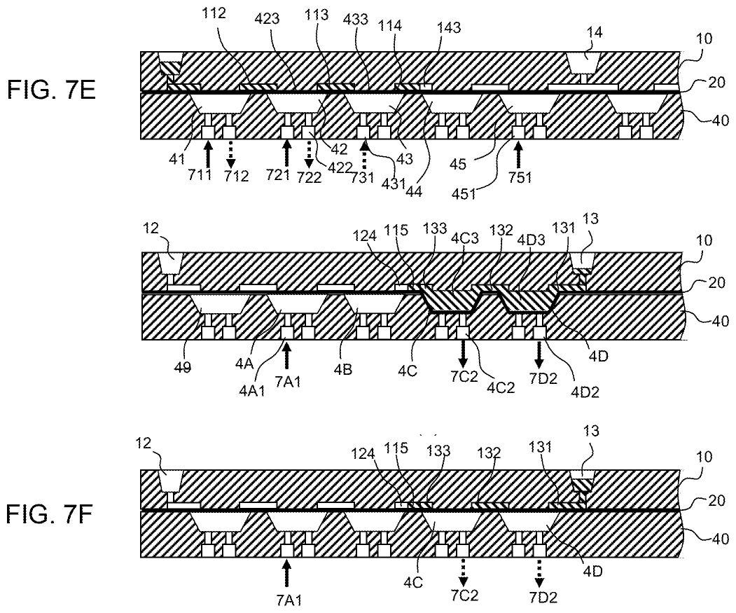

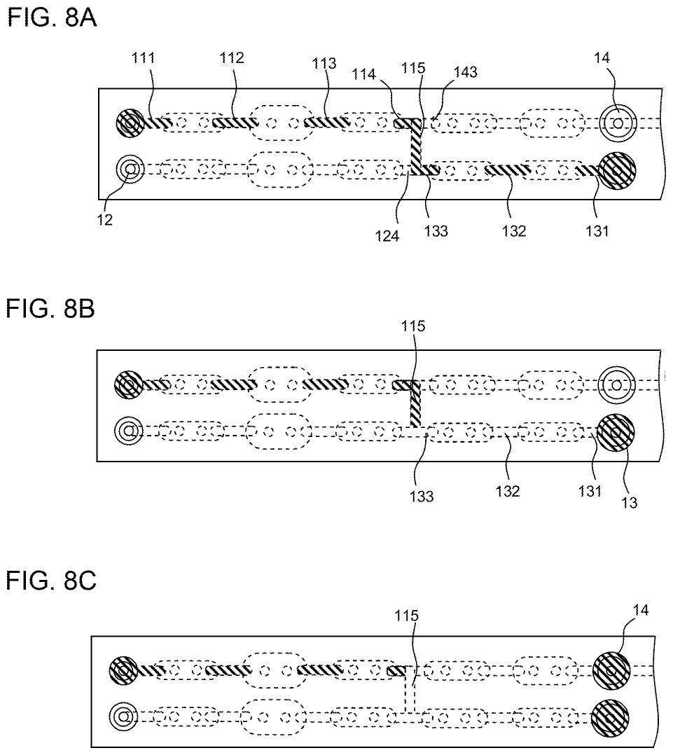

FIG. 6 is a flowchart illustrating the sample introduction operation flow through opening/closing control for the pressurization electromagnetic valve and the depressurization electromagnetic valve of the sample processing device of the present example, FIGS. 7a and 7b are explanatory views of the sample introduction operation, and FIG. 8 is an explanatory view illustrating a sample holding state. Note that the solid arrows illustrated in FIGS. 7a and 7b indicate that the electromagnetic valves corresponding to the pressurization pipe and the depressurization pipe are opened, the upward solid arrow indicates that the recess is pressurized when the pressurization electromagnetic valve is opened, and the downward solid arrow indicates that the recess is depressurized when the depressurization electromagnetic valve is opened. At a portion without the solid arrow, the electromagnetic valve is closed, but a dashed arrow is used in the description of the referenced drawing to particularly describe that the electromagnetic valve is closed. That is, the upward dashed arrow indicates that the pressurization electromagnetic valve is switched from open to close, and the downward dashed arrow indicates that the depressurization electromagnetic valve is switched from open to close.

(A) of FIG. 6 and (A) of FIG. 7a (cross-section AA) are in a state at a point of time of the aforementioned analysis operation start in which the sample 80 is held in the sample well 11. That is, in (A) of FIG. 7a, because the sample sealing recess pressurization electromagnetic valve 711 is opened, air flows in from the sample sealing recess pressurization pipe 411 and pressurizes the sample sealing recess 41, and the sample sealing recess depressurization electromagnetic valve 712 on the sample sealing recess depressurization pipe 412 side is closed. Moreover, although not illustrated, the reagent is held in the reagent well 15, and similarly the reagent sealing recess pressurization electromagnetic valve 7F1 is opened, and similarly the reagent sealing recess 4F is pressurized.

Next, as illustrated in (B) of FIG. 6 and (B) of FIG. 7a (cross-section AA), when the sample flow recess pressurization electromagnetic valve 721 is opened, air flows in from the sample flow recess pressurization pipe 421 and pressurizes the sample flow recess 42, and the sample sealing recess pressurization electromagnetic valve 711 is closed to stop inflow of air from the sample sealing recess pressurization pipe 411, and the sample sealing recess depressurization electromagnetic valve 712 is opened such that the air outflows from the sample sealing recess depressurization pipe 412 to depressurizes the sample sealing recess 41. At this time, because the membrane 20 is pulled to the bottom surface of the sample sealing recess 41, a sample sealing portion gap 413 is created between the membrane 20 and the analysis chip 10, and the sample 80 is drawn from the sample well 11 to the sample sealing portion gap 413 via the sample sealing upstream groove 111.

Next, as illustrated in (C) of FIG. 6 and (C) of FIG. 7a (cross-section AA), when the sample introduction recess pressurization electromagnetic valve 731 is opened with the sample sealing recess depressurization electromagnetic valve 712 being opened, air flows in from the sample introduction recess pressurization pipe 431 to pressurize the sample introduction groove 43, and the sample flow recess pressurization electromagnetic valve 721 is closed to stop inflow of air from the sample flow recess pressurization pipe 421, and the sample flow recess depressurization electromagnetic valve 722 is opened such that the air outflows from the sample delivery recess depressurization pipe 422 to depressurize the sample flow recess 42. At this time, because the membrane 20 is pulled toward the bottom surface of the sample flow recess 42, a sample flow portion gap 423 is created between the membrane 20 and the analysis chip 10, and the sample 80 is drawn to the sample flow portion gap 423 via the sample flow upstream groove 112 from the sample sealing portion gap 413.

Next, as illustrated in (D) of FIG. 6 and (D) of FIG. 7a (cross-section AA), when the sample sealing recess depressurization electromagnetic valve 712 is closed with the sample introduction recess pressurization electromagnetic valve 731 and the sample introduction recess depressurization electromagnetic valve 722 being opened, outflow of air from the sample sealing recess depressurization pipe 412 is stopped, and the sample sealing recess pressurization electromagnetic valve 711 is opened such that the air flows in from the sample sealing recess pressurization pipe 411 to pressurize the sample sealing recess 41. At this time, the sample sealing recess 41 and the sample introduction recess 43 are pressurized such that the sample flow upstream groove 112 and the sample introduction upstream groove 113 are sealed and the sample 80 is held in the sample flow portion gap 423.

Next, as illustrated in (E) of FIG. 6 and (E) of FIG. 7b (cross-section AA and cross-section BB), with the sample sealing recess pressurization electromagnetic valve 711 being opened, new two recesses, i.e., the stirring inlet recess 45 and the air flow recess 4A, are pressurized, and two recesses, i.e., the sample discharge recess 4C and the sample disposal recess 4D, are depressurized. That is, the stirring inlet recess pressurization electromagnetic valve 751 is opened such that the air flows in from the stirring inlet recess pressurization pipe 451 to pressurize the stirring inlet recess 45, the air flow recess pressurization electromagnetic valve 7A1 is opened such that the air flows in from the air flow recess pressurization pipe 4A1 to pressurize the air flow recess 4A, the sample discharge recess depressurization electromagnetic valve 7C2 is opened such that the air flows out from the sample discharge recess depressurization pipe 4C2 to depressurize the sample discharge recess 4C, and the sample disposal recess depressurization electromagnetic valve 7D2 such that the air flows out from the sample disposal recess depressurization pipe 4D2 to depressurize the sample disposal recess 4D. In this state, among the four grooves connected to the metering groove 115, i.e., the sample introduction downstream groove 114, the sample discharge upstream groove 133, the air branch groove 124, and the sample branch groove 143, the air flow recess 4A present between the air branch groove 124 and the air intake well 12 present upstream thereof is pressurized, and the membrane 20 is pressed against the lower surface side of the analysis chip 10 and the air branch groove 124 is sealed, and similarly the stirring inlet recess 45 present between the sample branch groove 143 and the stirring well 14 present downstream thereof is pressurized, and the membrane 20 is pressed against the lower surface side of the analysis chip 10 and the sample branch groove 143 is sealed. Meanwhile, two recesses present between the sample discharge upstream groove 133 and the sample disposal well 13 present downstream thereof, i.e., the sample discharge recess 4C and the sample disposal recess 4D are depressurized, and the membrane 20 is pulled to the bottom surface of the recesses to create a gap between the lower surface of the analysis chip 10 and the membrane 20, and the sample discharge upstream groove 133 is in communication with the sample disposal well 13.

In such a state, the sample introduction recess pressurization electromagnetic valve 731 is closed to stop inflow of the air from the sample introduction recess pressurization pipe 431, and the sample flow recess depressurization electromagnetic valve 722 is closed to stop outflow of the air from the sample flow recess depressurization pipe 422. At this time, the membrane 20 of the sample flow recess 42 tends to return to the original state by elasticity and pushes out the sample 80 from the sample flow portion gap 423. However, the sample flow upstream groove 112 is sealed under pressurization of the sample sealing recess 41 and does not allow outflow. Moreover, regarding the sample branch groove 143 and the air branch groove 124, the cutout recess 44 and the air introduction recess 4B are not pressurized, but because the stirring inlet recess 45 and the air flow recess 4A, which are present ahead, are pressurized and sealed, when the sample or the air flows into the sample branch groove 143 or the air branch groove 124, the membrane of the cutout recess 44 and the air introduction recess 4B needs to be separated from the lower surface of the analysis chip 10 against the elasticity of the membrane. Meanwhile, in sample discharge upstream 133, both the sample discharge recess 4C and the sample disposal recess 4D are depressurized and are communicated with the sample disposal well 13 such that the sample 80 and the air can flow out. That is, the sample 80 passes the sample flow portion gap 423 and the sample introduction upstream groove 113, enters the sample introduction portion gap 433 between the membrane 20 and the analysis chip 10 at the sample introduction groove 43, is introduced into the metering groove 115 from the sample introduction downstream groove 114, further passes the sample discharge upstream groove 133, the sample discharge portion gap 4C3 between the membrane 20 and the analysis chip 10 at the sample discharge recess 4C, the sample discharge downstream groove 132, the sample disposal portion gap 4D3 between the membrane 20 and the analysis chip 10 at the sample disposal recess 4D, and the sample disposal downstream groove 131, and flows out to the sample disposal well 13.

Finally, the sample flow recess pressurization pipe 721 is opened to pressurize the sample flow recess 42 to press the membrane against the analysis chip 10 such that the sample 80 is fully pushed out.

Next, as illustrated in (F) of FIG. 6 and (F) of FIG. 7b (cross-section BB), when the sample discharge recess depressurization electromagnetic valve 7C2 and the sample disposal recess depressurization electromagnetic valve 7D2 are closed with the air introduction recess pressurization electromagnetic valve 7A1 being opened to stop outflow of the air from the sample discharge recess 4C and the sample disposal recess 4D. Note that, at this time, although not illustrated, the sample flow recess pressurization electromagnetic valve 721 and the stirring inlet recess pressurization electromagnetic valve 751 remain opened. In this way, at the sample discharge portion gap 4C3 and the sample disposal portion gap 4D3, the membrane returns to the lower surface side of the analysis chip 10 by elasticity, and the sample 80 is pushed out to the sample disposal well 13.

In this state, as illustrated in (A) of FIG. 8, the metering groove 115 is filled with the sample 80. Note that the sample sealing upstream groove 111, the sample flow upstream groove 112, the sample introduction upstream groove 113, the sample introduction downstream groove 114, the sample discharge upstream groove 133, the sample discharge downstream groove 132, and the sample disposal downstream groove 131 are also filled with the sample 80, but the sample 80 does not enter the air branch groove 124, the groove on the air intake well 12 side upstream thereof, the sample branch groove 143, or the groove on the stirring well 14 side downstream thereof.

The above is the sample introduction 212 of FIG. 5, i.e., the operation of introducing the sample 80 held in the sample well 11 into the metering groove 115.

Note that, in the present example, in (E) and (F) of FIG. 7b, after the introduction of the sample into the metering groove 115, the recesses closest to the metering groove 115, i.e., the sample introduction groove 43, the cutout recess 44, the air introduction recess 4B, and the sample discharge recess 4C are not pressurized. This is because when the recesses closest to the metering groove 115 are pressurized, there is a possibility that the membrane is pushed up by the metering groove 115 and reduces the volume to influence the metering property. For example, in (E) of FIG. 7b, when the air flow recess 4A is not pressurized, but the air introduction recess 4B is pressurized, the pressurized air pushes up the membrane 20 below the air branch groove 124 and further pushes up the membrane 20 below the branch groove 115. Thus, although only slightly, the volume of the metering groove 115 is reduced and the amount of liquid to be held is reduced. When the pressurization of the air introduction recess 4B is stopped after end of the introduction of the sample into the metering groove 115, the membrane 20 at the metering groove 115 returns to the original state by elasticity, and the volume of the metering groove 115 returns to a predetermined volume. At this time, the metering property is not lost when the liquid returns to the metering groove 115, but, when the air enters, the amount of liquid remains reduced.

Therefore, with the analysis chip 10 of the present example, at and after a point of time when the sample is introduced into the metering groove 115, the four recesses closest to the metering groove 115 are not pressurized.

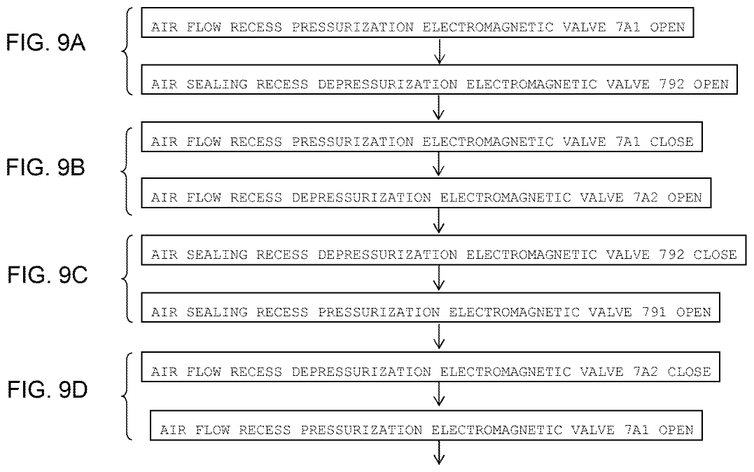

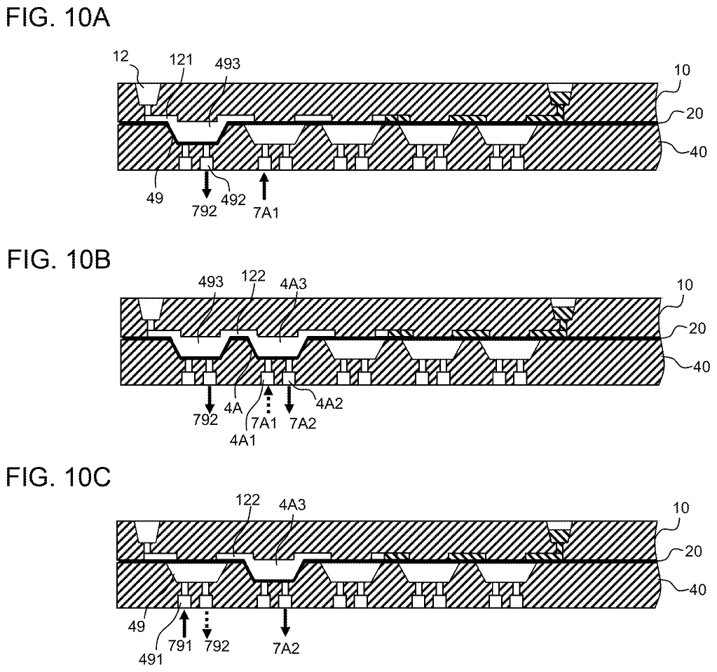

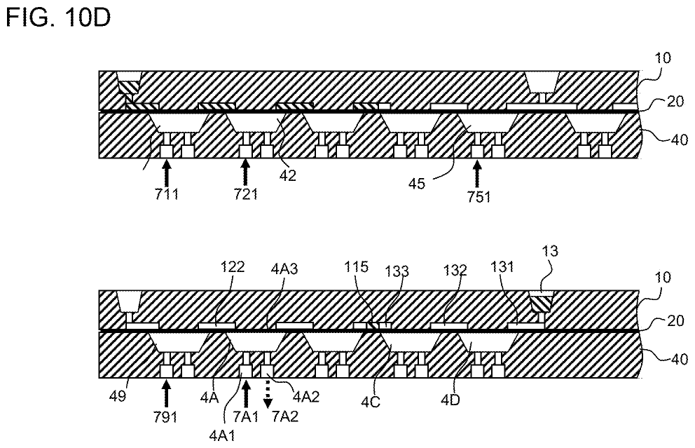

Next, the sample disposal 213 of FIG. 5 is described in conjunction with FIGS. 9, 10a, and 10b.

FIG. 9 is a flowchart illustrating a sample disposal operation flow through opening/closing control for the pressurization electromagnetic valve and the depressurization electromagnetic valve of the sample processing device of the present example, and FIGS. 10a and 10b are explanatory views of the sample disposal operation.

(A) of FIG. 9 and (A) of FIG. 10a (cross-section BB) are operations following (F) of FIG. 6 and (F) of FIG. 7b in which the air sealing recess depressurization electromagnetic valve 792 is opened with the air flow recess pressurization electromagnetic valve 7A1 being opened such that the air flows out from the air sealing recess depressurization pipe 492 to depressurize the air sealing recess 49. At this time, because the membrane 20 is pulled to the bottom surface of the air sealing recess 49, an air sealing portion gap 493 is created between the membrane 20 and the analysis chip 10, and the air is drawn to the air sealing portion gap 493 from the air intake well 12 via the air sealing upstream groove 121.

Next, as illustrated in (B) of FIG. 9 and (B) of FIG. 10a (cross-section BB), the air flow recess pressurization electromagnetic valve 7A1 is closed with the air sealing recess depressurization electromagnetic valve 792 being opened to stop inflow of the air from the air flow recess pressurization pipe 4A1, and the air flow recess depressurization electromagnetic valve 7A2 is opened such that the air flows out from the air flow recess depressurization pipe 4A2 to depressurize the air flow recess 4A. At this time, because the membrane 20 is pulled to the bottom surface of the air flow recess 4A, an air flow portion gap 4A3 is created between the membrane 20 and the analysis chip 10, and the air is drawn to the air flow portion gap 4A3 from the air sealing portion gap 493 via the air flow upstream groove 122.

Next, as illustrated in (C) of FIG. 9 and (C) of FIG. 10a (cross-section BB), the air sealing recess depressurization electromagnetic valve 792 is closed with the air flow recess depressurization electromagnetic valve 7A2 being opened to stop outflow of the air from the air sealing recess depressurization pipe 492, and the air sealing recess pressurization electromagnetic valve 791 is opened such that the air flows in from the air sealing recess pressurization pipe 491 to pressurize the air sealing recess 49. At this time, when the air sealing recess 49 is pressurized, the air flow upstream groove 122 is sealed and the air is held in the air flow portion gap 4A3.

Next, as illustrated in (D) of FIG. 9 and (D) of FIG. 10b (cross-section AA and cross-section BB), the air flow recess depressurization electromagnetic valve 7A2 is closed with the air sealing recess pressurization electromagnetic valve 791 being opened to stop outflow of the air from the air flow recess depressurization pipe 4A2, and the air flow recess pressurization electromagnetic valve 7A1 is opened such that the air flows in from the air flow recess pressurization pipe 4A1 to pressurize the air flow recess 4A. At this time, the sample flow recess 42 and the stirring inlet recess 45 are pressurized in a state where the sample flow recess pressurization electromagnetic valve 721 and the stirring inlet recess pressurization electromagnetic valve 751 are opened. In this way, at the air flow recess 4A, the membrane 20 tends to push out the air in the air flow portion gap 4A3. However, because the air sealing recess 49, the sample flow recess 42, and the stirring inlet recess 45 are pressurized, the air in the air flow portion gap 4A3 cannot move toward the air sealing upstream groove 122 and the metering groove 115, but moves, from the sample discharge upstream groove 133, to the gap between the membrane 20 and the analysis chip 10 at the non-pressurized sample discharge recess 4C, the sample discharge downstream groove 132, the gap between the membrane 20 and the analysis chip 10 at the non-pressurized sample disposal recess 4D, and the sample disposal downstream groove 131 to push out the sample to the sample disposal well 13.

In this state, as illustrated in (B) of FIG. 8, the sample 80 held in (A) of FIG. 8 in the sample discharge upstream groove 133, the sample discharge downstream groove 132, and the sample disposal downstream groove 131 flows out to the sample disposal well 13.

The above is the sample disposal 213 of FIG. 5, i.e., the operation of discharging the sample present in the sample discharge upstream groove 133, the sample discharge downstream groove 132, and the sample disposal downstream groove 131 present downstream the metering groove 115 to the sample disposal well 13.

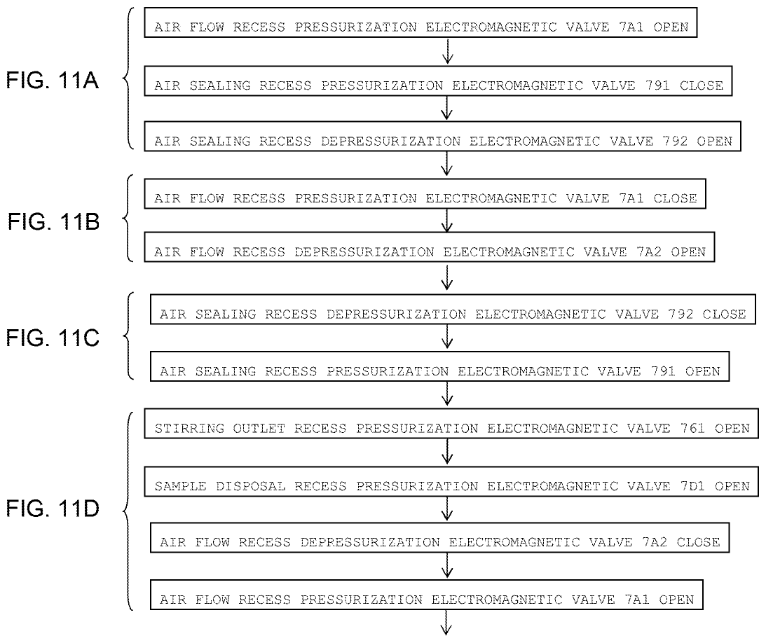

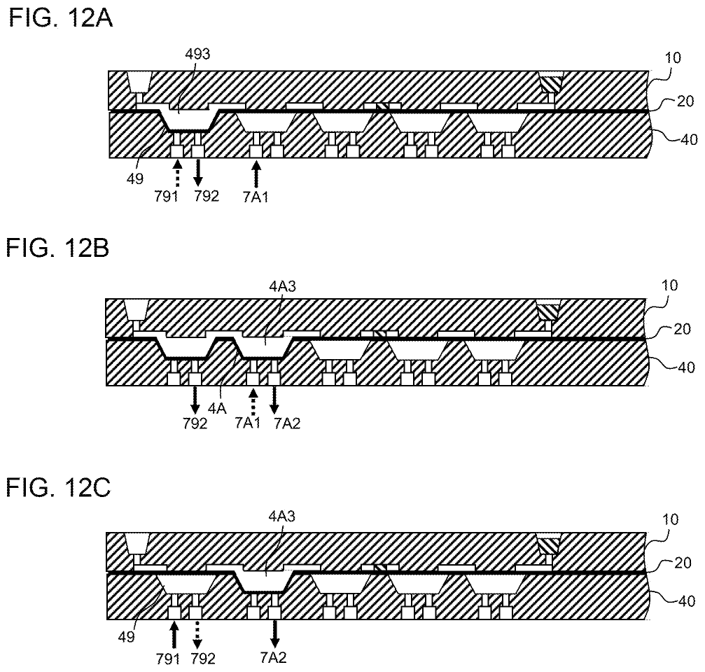

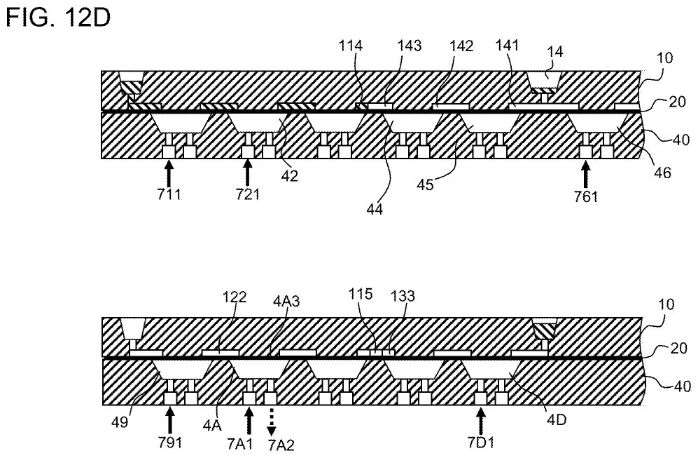

Next, the sample cutout 214 of FIG. 5 is described in conjunction with FIGS. 11, 12a, and 12b.

FIG. 11 is a flowchart illustrating a sample cutout operation flow through opening/closing control for the pressurization electromagnetic valve and the depressurization electromagnetic valve of the sample processing device of the present example, and FIGS. 12a and 12b are explanatory views of the sample cutout operation.

(A) of FIG. 11 and (A) of FIG. 12a (cross-section BB) are operations following (D) of FIG. 9 and (D) of FIG. 10b in which the operations from (A) to (C) are exactly the same except that the air sealing recess pressurization electromagnetic valve 791 is closed first. That is, in (A), the air sealing recess pressurization electromagnetic valve 791 is closed with the air flow recess pressurization electromagnetic valve 7A1 being opened, and the air sealing recess depressurization electromagnetic valve 792 is opened to depressurize the air sealing recess 49 such that the air is drawn to the air sealing portion gap 493. In (B), the air flow recess pressurization electromagnetic valve 7A1 is closed and the air flow recess depressurization electromagnetic valve 7A2 is opened to depressurize the air flow recess 4A such that the air is drawn to the air flow portion gap 4A3. In (C), the air sealing recess depressurization electromagnetic valve 792 is closed and the air sealing recess pressurization electromagnetic valve 791 is opened to pressurize and seal the air sealing recess 49 so as to hold the air in the air flow portion gap 4A3.

Next, as illustrated in (D) of FIG. 11 and (D) of FIG. 12b (cross-section AA and cross-section BB), the stirring outlet recess pressurization electromagnetic valve 761 and the sample disposal recess pressurization electromagnetic valve 7D1 are opened to pressurize and seal the stirring outlet recess 46 and the sample disposal recess 4D. At this time, the sample flow recess pressurization electromagnetic valve 721 is also opened to pressurize and seal the sample flow recess 42. In this state, when the air flow recess depressurization electromagnetic valve 7A2 is closed and the air flow recess pressurization electromagnetic valve 7A1 is opened, at the air flow recess 4A, the membrane 20 tends to push out the air in the air flow portion gap 4A3, but because the air flow recess 49 and the sample disposal recess 4D are pressurized, the air in the air flow portion gap 4A3 cannot move toward the air introduction upstream groove 122 and the sample discharge upstream groove 133, but move to the metering groove 115 to push out the sample in the metering groove 115. However, because the sample flow recess 42 is sealed, the sample cannot move toward the sample introduction downstream groove 114, but moves, from the sample branch groove 143, to the gap between the membrane 20 and the analysis chip 10 at the non-pressurized cutout recess 44, the cutout downstream groove 142, the gap between the membrane 20 and the analysis chip 10 at the non-pressurized stirring inlet recess 45, and the stirring inlet downstream groove 141, and is pushed out to the stirring well 14.

In this state, as illustrated in (C) of FIG. 8, the sample held in the metering groove 115 in (A) and (B) of FIG. 8 flows out to the stirring well 14.

The above is the sample cutout 214 of FIG. 5, i.e., the operation of cutting out the sample in the metering groove 115 to the stirring well 14.

The operations of the sample introduction 212, the sample disposal 213, and the sample cutout 214 of FIG. 5 described above are the sample metering 211. That is, the sample in the sample well 11 is flown to the one-end sample disposal well 13 such that the sample is held in the metering groove 115 and only the sample held in the metering groove 115 is forced out by the air to the stirring well 14, and thus a certain amount of sample, i.e., the same liquid amount as the volume of the metering groove 115, is held in the stirring well 14.

Note that, in the present example, the sample introduction 212 is followed by the sample disposal 213 and then the sample cutout 214, but the operation of the sample disposal 213 may be omitted, and the sample introduction 212 may be followed by the sample cutout 214.

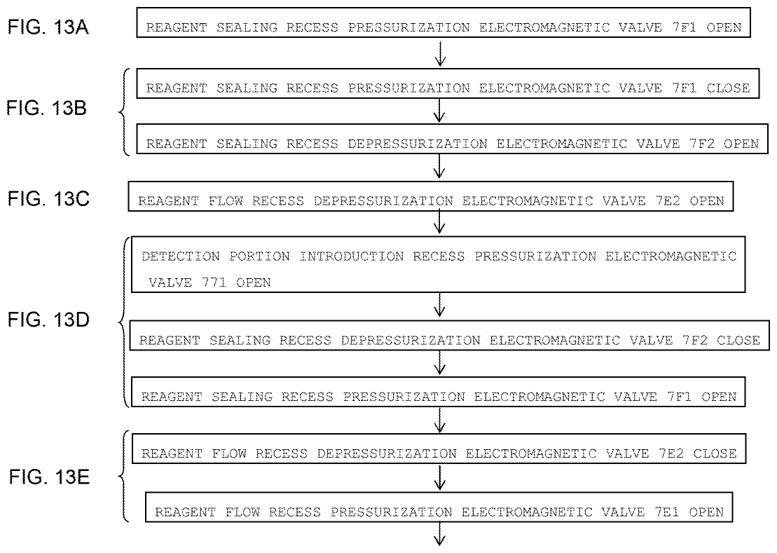

When the sample metering 211 of FIG. 5 ends, next the reagent introduction 215 is performed. This operation is to move the reagent in the reagent well 15 to the stirring well 14 in FIG. 1 and is the same operation as the sample introduction 212, and therefore the operation flow of the reagent introduction under control of the electromagnetic valve is illustrated in FIG. 13, and the operation is described with reference to the reference numerals of FIGS. 1 and 3.

(A) of FIG. 13 is an initial state in which the reagent sealing recess pressurization electromagnetic valve 7F1 is opened, the reagent sealing recess 4F is pressurized and sealed, and the reagent in the reagent well 15 does not flow out.

In (B) of FIG. 13, the reagent sealing recess pressurization electromagnetic valve 7F1 is closed and the reagent sealing recess depressurization electromagnetic valve 7F2 is opened to depressurize the reagent sealing recess 4F, and the reagent is drawn from the reagent well 15 to the gap created between the membrane 20 and the lower surface of the analysis chip 10.

In (C) of FIG. 13, the reagent flow recess depressurization electromagnetic valve 7E2 is opened to depressurize the reagent flow recess 4E, and the reagent is further drawn to the gap created between the membrane 20 and the lower surface of the analysis chip 10.

In (D) of FIG. 13, the detection portion introduction recess pressurization electromagnetic valve 771 is opened to pressurize and seal the detection portion introduction recess 47, and furthermore the reagent sealing recess depressurization electromagnetic valve 7F2 is closed and the reagent sealing recess pressurization electromagnetic valve 7F1 is opened to pressurize and seal the air sealing recess 4F.

In (E) of FIG. 13, the reagent flow recess depressurization electromagnetic valve 7E2 is closed and the reagent flow recess pressurization electromagnetic valve 7E1 is opened to pressurize the reagent flow recess 4E to push out the reagent. At this time, because the reagent sealing recess 4F is sealed, the reagent cannot move to the reagent flow downstream groove 152, but moves from the reagent flow upstream groove 153 to the junction groove 154. Furthermore, because the detection portion introduction recess 47 is sealed, the reagent cannot move to the detection portion introduction upstream groove 165, but moves from the stirring outlet downstream groove 145 to the gap between the membrane 20 and the analysis chip 10 at the non-pressurized stirring outlet recess 46, and the stirring outlet upstream groove 144, and is pushed out to the stirring well 14.

The above is the reagent introduction 215 of FIG. 5, i.e., the operation of moving the reagent in the reagent well 15 to the stirring well 14.

In this way, the sample is held in the stirring well 14 by the sample metering 211, and the reagent is held in the stirring well 14 by the reagent introduction 215. Note that, because it is sufficient if the sample and the reagent are held in the stirring well 14, the reagent introduction 215 may be followed by the reagent metering 211.

The sample is metered by the volume of the metering groove, and the reagent is metered by the volume of the reagent flow recess 4E, technically by the volume from which the thickness of the membrane 20 is subtracted. Alternatively, the reagent is metered by the amount of injection to the reagent well 15. That is, in the case of metering with the reagent flow recess 4E, the reagent in an amount larger than the amount of liquid to be metered is injected to the reagent well 15, and the operation of the reagent introduction 215 is performed, such that the predetermined amount of liquid can be moved to the stirring well 14. Alternatively, in the case of metering by the amount of injection to the reagent well 15, it is sufficient if an amount smaller than the volume of the reagent flow recess 4E is injected to the reagent well 15. In the case of metering a large amount of liquid, it is sufficient if the operation of the reagent introduction 215 is performed multiple times.

Note that, because the membrane 20 is deformed to fluidize a liquid, when the amount of deformation is too small, the metering property is difficult to obtain. Therefore, in the case of metering a small amount of liquid, it is necessary in the reagent introduction 215 that the reagent flow recess be small to reduce the amount of deformation of the membrane 20, whereas the method using the metering groove 115 used in the sample metering 211 is not required to reduce the sample flow recess 42 and is suitable for metering of a small amount of liquid. Accordingly, which to use: the sample metering 211 or the reagent introduction 215 depends on the amount of liquid and the specification of the metering reproducibility.

In the present example, the metering of the sample uses the metering groove 115, and the metering of the reagent uses the volume of the reagent flow recess, but a conceivable method would be to use the metering groove to meter the reagent, i.e., two metering grooves for the sample and the reagent, or use of a single metering groove in order.

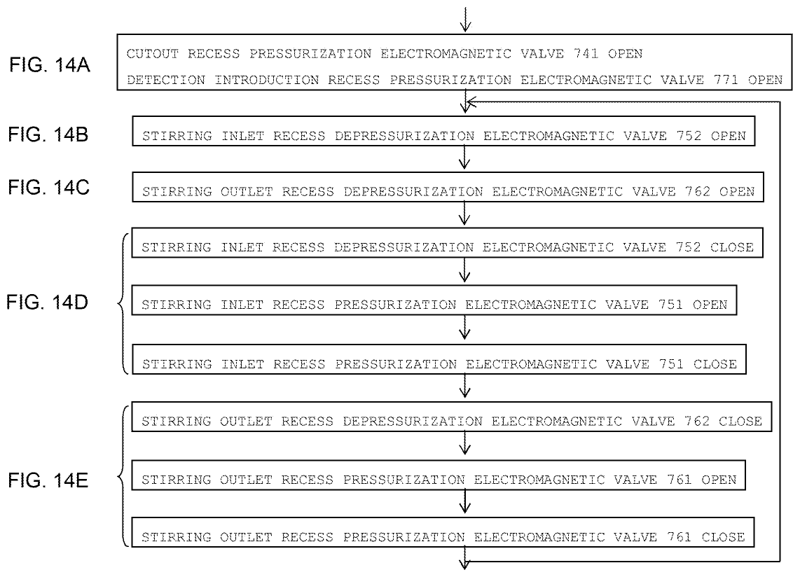

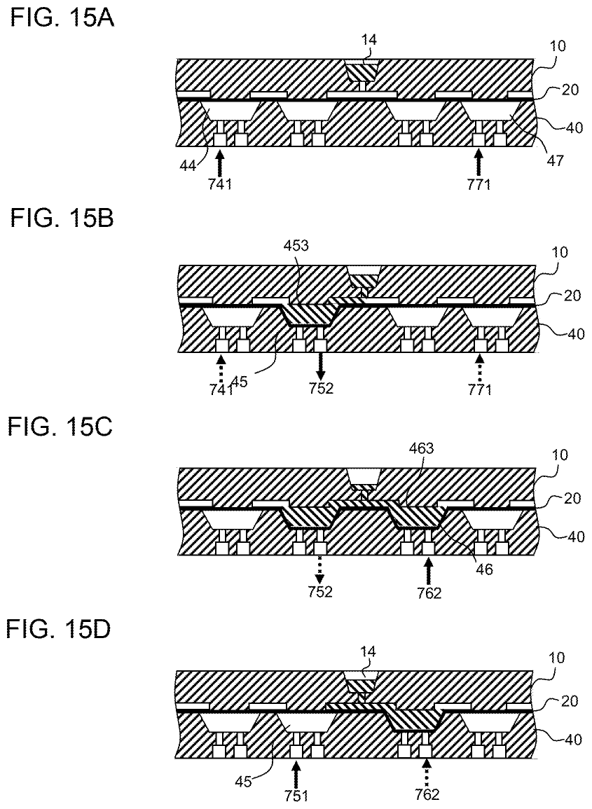

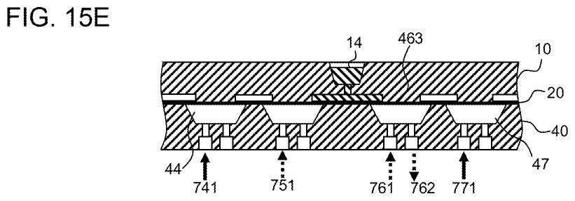

Next, the stirring 216 of FIG. 5 is described in conjunction with FIGS. 14, 15a, and 15b.

FIG. 14 is a flowchart illustrating a stirring operation flow through opening/closing control for the pressurization electromagnetic valve and the depressurization electromagnetic valve of the sample processing device of the present example, and FIGS. 15a and 15b are explanatory views of the stirring operation.

(A) of FIG. 14 and (A) of FIG. 15a (cross-section AA) are a state in which the sample and the reagent are held in the stirring well 14, and the cutout recess pressurization electromagnetic valve 741 and the detection introduction recess pressurization electromagnetic valve 771 are opened to pressurize and seal the cutout recess 44 and the detection introduction recess 47.

In (B) of FIG. 14 and (B) of FIG. 15a (cross-section AA), the stirring inlet recess depressurization electromagnetic valve 752 is opened to depressurize the stirring inlet recess 45, and the liquid is drawn to the stirring inlet portion gap 453, which is a gap created between the membrane 20 and the analysis chip 10.

In (C) of FIG. 14 and (C) of FIG. 15a (cross-section AA), the stirring outlet recess depressurization electromagnetic valve 762 is opened to depressurize the stirring outlet recess 46 and the liquid is drawn to the stirring outlet portion gap 463, which is a gap created between the membrane 20 and the analysis chip 10.

In (D) of FIG. 14 and (D) of FIG. 15a (cross-section AA), the stirring inlet recess depressurization electromagnetic valve 752 is closed and the stirring inlet recess pressurization electromagnetic valve 751 is opened to pressurize the stirring inlet recess 45, the liquid of the stirring inlet portion gap 453 is returned to the stirring well 14, and the stirring inlet recess pressurization electromagnetic valve 751 is closed.

In (E) of FIG. 14 and (E) of FIG. 15b (cross-section AA), the stirring outlet recess depressurization electromagnetic valve 762 is closed and the stirring outlet recess pressurization electromagnetic valve 761 is opened, the liquid of the stirring outlet portion gap 463 is returned to the stirring well 14, and the stirring outlet recess pressurization electromagnetic valve 761 is closed.

When the aforementioned manipulations from (B) to (E) are repeated, the liquid in the stirring well 14 is moved to the stirring inlet recess 45 and the stirring outlet recess 46, and is stirred every time the liquid is returned.

The above is the operation of the stirring 216 of FIG. 5.

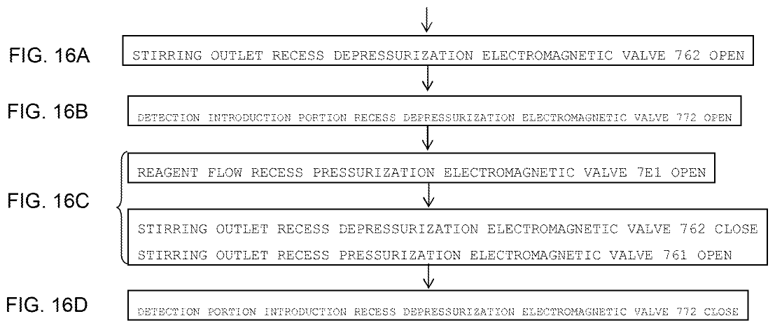

Next, the measurement 217 of FIG. 5 is described in conjunction with FIGS. 16, 1 and 3. FIG. 16 is a flowchart illustrating a measurement operation flow through opening/closing control for the pressurization electromagnetic valve and the depressurization electromagnetic valve of the sample processing device of the present example.

In (A) of FIG. 16, the stirring outlet recess depressurization electromagnetic valve 762 is opened to depressurize the stirring outlet recess 46, and the mixture held in the stirring well 14 after the end of the stirring is sucked from the stirring outlet upstream groove 144.

Next, in (B) of FIG. 16, the detection introduction portion recess depressurization electromagnetic valve 772 is opened to depressurize the detection portion introduction recess 47, and the mixture is sucked from the stirring outlet downstream groove 145 and the detection portion upstream groove.

Next, in (C) of FIG. 16, the reagent flow recess pressurization electromagnetic valve 7E1 is opened to pressurize and seal the reagent flow recess 4E, and the stirring outlet recess depressurization electromagnetic valve 762 is closed and the stirring outlet recess pressurization electromagnetic valve 761 is opened to pressurize the stirring outlet recess 46.

Next, in (D) of FIG. 16, the detection portion introduction recess depressurization electromagnetic valve 772 is closed. At this time, the membrane 20 of the detection portion introduction recess 47 tends to return to the lower surface side of the analysis chip 10 by elasticity and pushes out the mixture. Because the stirring outlet recess 46 and the reagent flow recess 4E are sealed, the mixture, while the mixture fills the detection portion downstream groove 164, the detection groove 163, and the mixture disposal upstream groove 162, moves to the gap between the membrane 20 and the analysis chip 10 at the non-pressurized mixture disposal recess 48 and the mixture disposal downstream groove 161, and the excessive mixture is pushed out to the mixture disposal well 16.

In this state, observation light is emitted from the observation window 34 of FIG. 2 to the detection groove 163, and data is acquired. The above is the operation of the measurement 217 of FIG. 5, and thus the analysis operation 207 of FIG. 4 ends.

Note that the detection groove 163 has a function of holding the liquid in a closed space, and Example 1 described in detail above indicates the analysis operation in which the observation light is emitted from the observation window 34 to the detection groove 164 and data is acquired, but the processing with the processing groove of the present example is not limited to analysis and detection. For example, two liquids may be stirred in the stirring 216 of FIG. 5, held in the detection groove 163 so as to react with each other, and then collected from the mixture disposal well 16, and alternatively processing other than optical measurement may be performed, e.g., holding the liquid in the detection groove 163 ton control the temperature.

According to the present invention, the membrane 20 can be deformed by air pressure to flow a liquid or a gas, and the one-end liquid can be held in the metering groove 115, and the liquid in the metering groove 115 can be forced out by air to meter the certain amount of liquid. In particular, a change in volume of the metering groove enables manipulation of metering a predetermined amount without changing the shapes of other grooves or recesses or the control operation for switching the electromagnetic valve.

### Example 2

As described with regard to the operation of (E) of FIG. 5, in Example 1, it is contrived that the four recesses closest to the metering groove 115 are not pressurized, but adjacent recesses are pressurized. Therefore, for example, in the operation of the sample introduction (212 of FIG. 5), when the sample is sent from the sample well 11 to the sample disposal well 13, five recesses are used. That is, the sample sealing recess 41, the sample flow recess 42, the sample introduction groove 43, the sample discharge recess 4C, and the sample disposal recess 4D.

However, according to the present invention, when the pressure of recesses is controlled to deform the membrane and move the fluid, the fluid can be moved when there are three recesses. That is, in the introduction of the reagent, the liquid can be delivered with the three recesses: the reagent sealing recess 4F, the reagent flow recess 4E, and the stirring outlet recess 46.

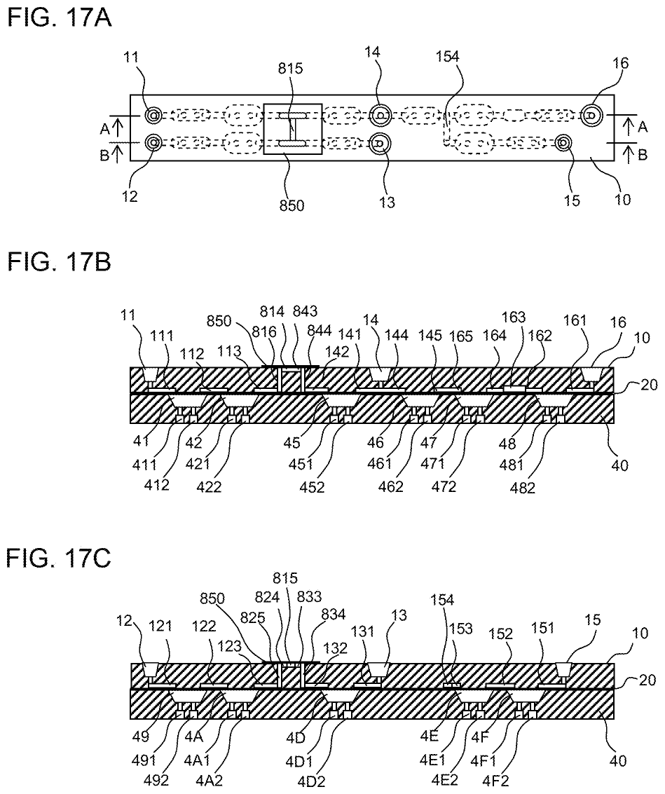

Thus, the sample processing device that achieves metering using three recesses is illustrated in FIG. 17. A difference from FIG. 1 is that the four recesses: the sample sealing recess 41, the sample flow recess 42, the sample introduction recess 43, the sample discharge recess 4C, and the sample disposal recess 4D, which are closest to the metering groove 115 illustrated in FIG. 1, are absent, and the metering groove 115 is provided on the upper surface side, not on the lower surface side of the analysis chip 10, i.e., the side that contacts the membrane 20. The same structures as those of FIG. 1 are designated the same reference numerals, and differences are as follows: a metering groove 815 present on the upper surface side of the analysis chip, a sample introduction vertical hole 816 communicating with the upper surface side of the analysis chip from the downstream end of the sample introduction upstream groove 113, a sample introduction downstream groove 814 communicating with the metering groove 815 further from the sample introduction vertical hole 816, a sample branch vertical hole 844 communicating with the upper surface side of the analysis chip from the downstream end of the cutout downstream groove 142, a cutout upstream groove 843 communicating with the metering groove 815 further from the sample branch vertical hole 844, an air introduction vertical hole 825 communicating with the upper surface side of the analysis chip from the downstream end of the air introduction upstream groove 123, an air branch groove 824 communicating with the metering groove 815 further from the air introduction vertical hole 825, a sample discharge vertical hole 834 communicating with the upper surface side of the analysis chip from the downstream end of the sample discharge downstream groove 132, and a sample discharge upstream groove 833 communicating with the metering groove 815 further from the sample discharge vertical hole 834. Note that the sample introduction downstream groove 814, the metering groove 815, the air branch groove 824, and the sample discharge upstream groove 833, which are provided on the upper surface side of the analysis chip 10, are sealed with a cover 850.

The sample metering 211 of FIG. 5 is the same as those of FIGS. 6 to 12a, and 12b described in Example 1, but the operation of controlling the four recesses closest to the metering groove 115 is excluded. At this time, in the case of the analysis chip 10 of FIG. 17, the recesses closest to the metering groove 815 are pressurized, but the metering groove 815, which is not in contact with the membrane 20, is not subject to influences of a change in volume due to deformation of the membrane, and thus metering property is not lost.

### Example 3

In Example 1, the sample held in the sample well 11 is delivered to the sample disposal well 13 and is introduced into the metering groove 115, and the sample introduced into the metering groove 115 is cut out to the stirring well 14 to meter the sample.

Before the sample is introduced from the sample well 11 to the metering groove 115, the air is present in the grooves from the sample well 11 to the metering groove 115, i.e., the sample sealing upstream groove 111, the sample flow upstream groove 112, the sample introduction upstream groove 113, and the sample introduction downstream groove 114, and when the sample is introduced, the air passes the metering groove 115 and is discharged to the sample disposal well 13. That is, as illustrated in (B) of FIG. 7a, when the sample 80 is drawn from the sample well 11 to the sample sealing portion gap 413 via the sample sealing upstream groove 111, the air present in the sample sealing upstream groove 111 is pulled to the downstream end (right side in the drawing) of the sample sealing portion gap 413, and next in (C) of FIG. 7, together with the air in the sample flow upstream groove 112, the sample is pulled to the downstream end (right side in the drawing) of the sample flow portion gap 423, such that the positional relationship between the sample and the air is invariably unchanged, and when the sample is held on the upstream side and the air is held in the downstream side, the air is discharged to the disposal well 13 when the sample flows.

However, depending on the shape or size of the gaps, e.g., the sample sealing portion gap 413, when the sample is drawn, there is a possibility that the positions of the sample and the air are reversed or the air breaks. If the positions of the sample and the air are reversed, there is a possibility that the air flows into the metering groove 115 after the sample is discharged to the sample disposal well 13 and the metering property is lost.

Thus, in the present example, a structure in which before the sample is introduced into the metering groove 115, the air in the grooves is removed to prevent entry of the air into the metering groove 115 is described.

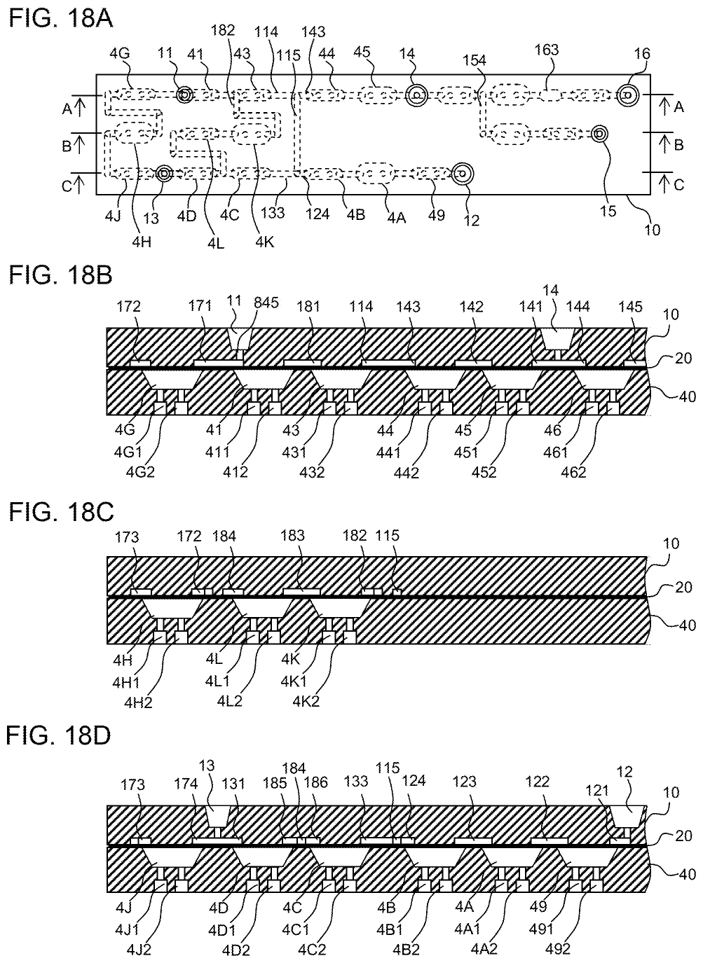

FIG. 18 illustrates an analysis chip including an air removal mechanism. Note that the same structures as those of FIG. 1 are designated the same reference numerals.

(A) of FIG. 18 is a view of the analysis chip 10 when viewed from the upper surface side, and (B), (C) and (D) of FIG. 1 are respectively an AA cross-section, a BB cross-section, and a CC cross-section of FIG. 1(A). Note that each cross-sectional view is a cross-sectional view of a portion related to the metering manipulation.

In FIG. 18, as compared with FIG. 1, a mechanism required for air removal is added or modified, and an added or modified portion is described in the description of the operation below.

The air removal manipulation is a manipulation that is performed immediately before the sample metering 211 of FIG. 5, and the manipulation flow is the same as that of FIG. 4. However, regarding the input manipulation 205 of FIG. 4, in Example 1, when the manipulator inputs the sample through the sample input window 32 to the sample well 11, the pressurization electromagnetic valve 711 is opened to pressurize the recess 41 so as to seal the groove 111 such that the sample does not flow out from the sample well 11, but in the present example, as illustrated in (B) of FIG. 18, in order to prevent the sample from flowing out from the sample holding vertical hole 845 and the vertical hole air introduction groove 171, which are present immediately below the sample well 11, both the sample sealing recess 41 and the vertical hole air introduction recess 4G are pressurized.

In the air removal manipulation, the air in the sample holding vertical hole 845 and the air present in the sample sealing downstream groove 181 (FIG. 18(B)) and the sample flow groove 182 (FIG. 18(A)) are removed.

First, the manipulation of removing the air in the sample holding vertical hole 845 is described. First, the vertical hole air introduction recess 4G is depressurized to pull the membrane 20, and the air in the sample holding vertical hole 845 and the air in the sample well 11 are drawn to the gap created between the membrane 20 and the analysis chip 10 above the vertical hole air introduction recess 4G. Next, the vertical hole air flow recess 4H is depressurized, and the air and the sample are drawn to the gap created between the membrane 20 and the analysis chip 10 above the vertical hole air flow recess 4H. Next, the vertical hole air introduction recess 4G is pressurized while the vertical hole air discharge recess 4J is pressurized, and the gap above the vertical hole air introduction recess 4G is closed to return the sample to the sample well 11. Next, the pressurization of the vertical hole air discharge recess 4J is stopped, and the depressurization of the vertical hole air flow recess 4H is stopped or the vertical hole air flow recess 4H is pressurized to discharge the sample to the sample disposal well 13. With this manipulation, the air in the sample holding vertical hole 845 is discharged to the sample disposal well 13, and the sample holding vertical hole 845 is filled with the sample.

Next, a manipulation of removing the air in the sample sealing downstream groove 181 and the sample flow groove 182 is described. First, the sample sealing recess 41 is depressurized, and the sample is drawn to the gap created between the membrane 20 and the analysis chip 10 above the sample sealing recess 41. At this time, because the air in the sample holding vertical hole 845 has already been removed, the air does not enter the aforementioned gap. Next, the sample flow recess 4K is depressurized, the sample is drawn, with the air in the sample sealing downstream groove 181 and the sample flow groove 182 being the top, to the gap created between the membrane 20 and the analysis chip 10 above sample flow recess 4K. Next, the sample sealing recess 41 is pressurized while the groove air discharge recess 4L and the sample introduction recess 43 are pressurized, the gap above the sample sealing recess 41 is closed, and the sample is returned to the sample well 11. Next, the pressurization of the groove air discharge recess 4L is stopped, and the sample discharge recess 4C is pressurized, but, in a state where the sample disposal recess 4D is not pressurized, the depressurization of the sample flow recess 4K is stopped or the sample flow recess 4K is pressurized, and the sample is discharged to the sample disposal well 13. With this manipulation, the air in the sample sealing downstream groove 181 and the sample flow groove 182 is discharged to the sample disposal well 13, and the sample sealing downstream groove 181 and the sample flow groove 182 are filled with the sample.

The above is the air removal manipulation, and subsequently the sample metering 211 of FIG. 5 is executed. The subsequent manipulation is the same as that of Example 1, but the arrangement of the recesses or grooves is different in some portions, and therefore only a difference is described below.

In the sample introduction 212 of FIG. 5, the sample held in the sample well 11 is delivered to the sample disposal well 13 so as to be introduced to the metering groove 115. In the example of FIG. 18, this manipulation is executed in the manner described below.

First, the sample sealing recess 41 is depressurized, and the sample is drawn to the gap created between the membrane 20 and the analysis chip 10 above the sample sealing recess 41. Next, when the sample flow recess 4K is depressurized, the sample is drawn to the gap created between the membrane 20 and the analysis chip 10 above the sample flow recess 4K. At this time, because the air in the sample sealing downstream groove 181 and the sample flow groove 182 has already been removed, the air does not enter the aforementioned gap. Next, the sample sealing recess 41 is pressurized while the groove air discharge recess 4L and the sample introduction recess 43 are pressurized, the gap above the sample sealing recess 41 is closed, and the sample is returned to the sample well 11. Next, the pressurization of the sample introduction groove 43 is stopped, and the depressurization of the sample flow recess 4K is stopped or the sample flow recess 4K is pressurized while the sample discharge recess 4C and the sample disposal recess 4D are depressurized, the sample is introduced into the metering groove 115 and is discharged to the sample disposal well 13. With this manipulation, the sample introduction downstream groove 114, the metering groove 115, the sample discharge upstream groove 133, and the like are filled with the sample.

Then, in the sample disposal 213 of FIG. 5, the air is sucked from the air intake well 12 and is sent to the sample disposal well 13, such that the sample of the sample discharge upstream groove 133 is discharged to the sample disposal well 13, and in the sample cutout 214 of FIG. 5, the air is sucked from the air intake well 12 and is sent to the stirring well 14, such that the sample of the metering groove 115 is discharged to the stirring well 14. A difference from Example 1 is that the flow path system of the air intake well 12, the air sealing recess 49, the air flow recess 4A, and the air introduction recess 4B and the flow path system of the sample disposal well 13, the sample disposal recess 4D, and the sample discharge recess 4C are changed to be positioned on the opposite side relative to the metering groove 115, and this is a change to use the sample disposal well 13 for discharge of the air in the air removal manipulation.

When the sample metering 211 of FIG. 5 ends, the manipulations of the reagent introduction 215, the stirring 216, and the measurement 217 are executed, and the arrangement (FIG. 18) of the flow path system related to these manipulations is the same as that of Example 1 (FIG. 1), and the operation is also entirely the same.

In the present example, the air in the sample holding vertical hole 845 and the air in the sample sealing downstream groove 181 and the sample flow groove 182 are removed. That is, the sample well 11 and the sample holding vertical hole 845 immediately therebelow are arranged above the sample sealing recess 41, an end of the vertical hole air introduction groove 171 is connected to the sample holding vertical hole 845, the other end is arranged above the vertical hole air introduction recess 4G, and when the vertical hole air introduction recess 4G is depressurized, the air in the sample holding vertical hole 845 is removed and the sample holding vertical hole 845 is filled with the sample. Therefore, even when the sample sealing recess 41 is depressurized in the next manipulation, the air will not be pulled. Moreover, an end of the sample sealing downstream groove 181 is arranged above the sample sealing recess 41, the other end is arranged above the sample introduction groove 43, an end of the sample flow groove 182 is arranged above the sample flow recess 4K, and the other end is brought to match the end of the sample sealing downstream groove 181 arranged above the sample introduction groove 43, and when the sample flow recess 4K is depressurized, the air in the sample sealing downstream groove 181 and the sample flow groove 182 is removed, and the sample sealing downstream groove 181 and the sample flow groove 182 are filled with the sample. Therefore, even when the sample is introduced into the metering groove 115 in the next manipulation, the air does not enter.

Note that although the air is also present in the sample introduction downstream groove 114 and the metering groove 115, because the cross-sectional area is small and a change in the cross-sectional area is small, the positions of the air and the sample in the grooves are not reversed, and when the air is not present on the upstream side of the sample introduction downstream groove 114, the air in the sample introduction downstream groove 114 and the metering groove 115 is pushed out such that the air does not remain in the metering groove 115.

In the present example, it is possible to prevent entry of the air into the metering groove 115 and ensure the metering property.

### REFERENCE SIGNS LIST

10 analysis chip
11 sample well
12 air intake well
13 sample disposal well
14 stirring well
15 reagent well
16 mixture disposal well
111, 112, 113, 114, 121, 122, 123, 131, 132, 141, 142, 144,
145, 151, 152, 153, 154, 161, 162, 164, 165, 171, 172, 173,
174, 181, 182, 183, 184, 185, 186, 814, 833 groove
115, 815 metering groove
124, 143, 824, 843 branch groove
163 detection groove
20 membrane
30 lid
31 rotary support portion
32 sample input window
33 reagent input window
34 observation window
40 drive portion
41, 42, 43, 44, 45, 46, 47, 48, 49, 4A, 4B, 4C, 4D, 4E, 4F, 4G, 4H, 4J, 4K, 4L recess
411, 421, 431, 441, 451, 461, 471, 481, 491, 4A1, 4B1, 4C1,
4D1, 4E1, 4F1, 4G1, 4H1, 4J1, 4K1, 4L1 pressurization pipe
412, 422, 432, 442, 452, 462, 472, 482, 492, 4A2, 4B2, 4C2,
4D2, 4E2, 4F2, 4G2, 4H2, 4J2, 4K2, 4L2 depressurization pipe
50 housing
51 locking mechanism
60 control portion
61 manipulation portion
70 air pipe
71 pressurization pump
711, 721, 731, 741, 751, 761, 771, 781, 791, 7A1, 7B1, 7C1,
7D1, 7E1, 7F1, 7G1, 7H1, 7J1, 7K1, 7L1 pressurization electromagnetic valve
72 depressurization pump
712, 722, 732, 742, 752, 762, 772, 782, 792, 7A2, 7B2, 7C2,
7D2, 7E2, 7F2, 7G2, 7H2, 7J2, 7K2, 7L2 depressurization electromagnetic valve
816, 825, 834, 844, 845 vertical hole

1. A sample processing device comprising:
an analysis chip including a flow path on a lower surface side;
a drive portion including a plurality of recesses on an upper surface side;
an elastic membrane positioned between the analysis chip and the drive portion; and
an air pressure control portion configured to switch whether the elastic membrane is closely attached to an analysis chip side or closely attached to a drive portion side, wherein
the analysis chip includes a metering flow path for metering a liquid and at least four branch flow paths branched from the metering flow path,
the drive portion includes a recess below each of an end of the four branch flow paths not on a metering flow path side, and
each recess is in communication with the air pressure control portion.

2. The sample processing device according to claim 1, wherein
two branch flow paths of the four branch flow paths are a liquid delivery flow path configured to deliver a liquid, and the remaining two branch flow paths are an air supply flow path configured to deliver a gas,
a further pair of flow path and recess is provided on an upstream side or downstream side of the liquid delivery flow path, and a further pair of flow path and recess is provided on an upstream side or downstream side of the air supply flow path, and
these recesses are also in communication with the air pressure control portion.

3. The sample processing device according to claim 1, wherein
two branch flow paths of the four branch flow paths are a liquid delivery flow path configured to deliver a liquid, and the remaining two branch flow paths are an air supply flow path configured to deliver a gas,
two further pairs of flow path and recess are provided on an upstream side or downstream side of the liquid delivery flow path, and two further pairs of flow path and recess are provided on an upstream side or downstream side of the air supply flow path, and
these recesses are also in communication with the air pressure control portion.

4. The sample processing device according to claim 2, wherein
the air pressure control portion controls movement of the elastic membrane, and delivers the liquid to the recess on the downstream side.

5. The sample processing device according to claim 2, wherein
the liquid delivery flow path is used to fill the metering flow path with the liquid, and then the air supply flow path is used to flow the liquid in the metering flow path to the downstream side.

6. The sample processing device according to claim 2 in a good shape such that an additional pair of branch flow path and recess is provided in a branch flow path, which is the liquid delivery flow path.

7. The sample processing device according to claim 3, wherein
the air pressure control portion controls movement of the elastic membrane, and delivers the liquid to the recess on the downstream side.

8. The sample processing device according to claim 3, wherein
the liquid delivery flow path is used to fill the metering flow path with the liquid, and then the air supply flow path is used to flow the liquid in the metering flow path to the downstream side.

9. The sample processing device according to claim 4, wherein
the liquid delivery flow path is used to fill the metering flow path with the liquid, and then the air supply flow path is used to flow the liquid in the metering flow path to the downstream side.

10. The sample processing device according to claim 3 in a good shape such that an additional pair of branch flow path and recess is provided in a branch flow path, which is the liquid delivery flow path.

11. The sample processing device according to claim 4 in a good shape such that an additional pair of branch flow path and recess is provided in a branch flow path, which is the liquid delivery flow path.
